(19) United States
(12) Patent Application Publication
(10) Pub. No.: US 2025/0253211 A1
(43) Pub. Date: Aug. 7, 2025

(54) SEMICONDUCTOR DEVICE

(71) Applicant: Rohm Co., Ltd., Kyoto (JP)

(72) Inventor: Ryuta KIMURA, Kyoto (JP)

(21) Appl. No.: 19/044,039

(22) Filed: Feb. 3, 2025

(30) Foreign Application Priority Data
Feb. 7, 2024 (JP) 2024-016764

(51) Int. Cl. H01L 23/495; H01L 23/00; H01L 23/31

(52) U.S. Cl. CPC H01L 23/49555; H01L 23/49513; H01L 24/48; H01L 23/3107; H01L 2224/48247

(57) ABSTRACT

The semiconductor device includes a semiconductor element, a first lead, a second lead, a conductive member connected to the semiconductor element and a pad portion, and a sealing resin. The second lead protrudes from the sealing resin in a first direction. The second lead has a metal layer provided on the pad portion and a protrusion protruding in the second direction. The protrusion has a first surface being positioned along the thickness direction, facing a pad portion side in the first direction and being covered by the sealing resin. The first surface has a first end on a root side and a second end on a tip side. The second end is located on a pad portion side as viewed from the first end in the first direction.

### TECHNICAL FIELD

The present disclosure relates to a semiconductor device.

### BACKGROUND ART

JP-A-2018-060908 shows an example of a conventional semiconductor device. The semiconductor device disclosed in this document is equipped with a semiconductor element, a lead, a wire, and a sealing resin. A metal layer such as Ag (silver) may be provided on a part of the lead to which the wire is connected.

### BRIEF DESCRIPTION OF THE DRAWINGS

FIG. 1 is a perspective view showing the semiconductor device according to a first embodiment of the present disclosure.

FIG. 2 is a plan view showing the semiconductor device according to the first embodiment of the present disclosure.

FIG. 3 is a partial plan view showing the semiconductor device in accordance with the first embodiment of the present disclosure.

FIG. 4 is an enlarged partial plan view showing the semiconductor device in accordance with the first embodiment of the present disclosure.

FIG. 5 is an enlarged partial cross-sectional view showing the semiconductor device in accordance with the first embodiment of the present disclosure.

FIG. 6 is a bottom view showing the semiconductor device according to the first embodiment of the present disclosure.

FIG. 7 is a side view showing the semiconductor device according to the first embodiment of the present disclosure.

FIG. 8 is a cross-sectional view along line VIII-VIII in FIG. 3.

FIG. 9 is a cross-sectional view along line IX-IX in FIG. 3.

FIG. 10 is an enlarged partial plan view showing an example of a manufacturing method of the semiconductor device according to the first embodiment of the present disclosure.

FIG. 11 is an enlarged partial plan view showing a first variation of the semiconductor device according to the first embodiment of the present disclosure.

FIG. 12 is an enlarged partial plan view showing a second variation of the semiconductor device according to the first embodiment of the present disclosure.

FIG. 13 is an enlarged partial plan view showing a third variation of the semiconductor device according to the first embodiment of the present disclosure.

FIG. 14 is an enlarged partial plan view showing a fourth variation of the semiconductor device according to the first embodiment of the present disclosure.

FIG. 15 is an enlarged partial plan view showing a fifth variation of the semiconductor device according to the first embodiment of the present disclosure.

FIG. 16 is an enlarged partial plan view showing a sixth variation of the semiconductor device according to the first embodiment of the present disclosure.

FIG. 17 is a partial plan view showing a semiconductor device according to a second embodiment of the present disclosure.

FIG. 18 is an enlarged partial plan view showing the semiconductor device according to the second embodiment of the present disclosure.

FIG. 19 is an enlarged partial plan view showing a first variation of the semiconductor device according to the second embodiment of the present disclosure.

### DETAILED DESCRIPTION OF EMBODIMENTS

The following is a detailed description of the preferred embodiments of the present disclosure with reference to the drawings.

The terms “first”, “second”, “third” and so forth in the present disclosure are used merely for identification and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with an object B” and “an object A is located on an object B with another object interposed between an object A and an object B”. Further, the phrase “an object A overlaps an object B as viewed in a certain direction” includes, unless otherwise specified, “an object A overlaps with the entirety of an object B” and “an object A overlaps with a part of an object B”. Further, in the present disclosure, the phrase “a plane A faces direction B (on one side or the other of direction B)” is not limited to the case where the angle of plane A with respect to direction B is 90°, but includes the case where plane A is inclined with respect to direction B.

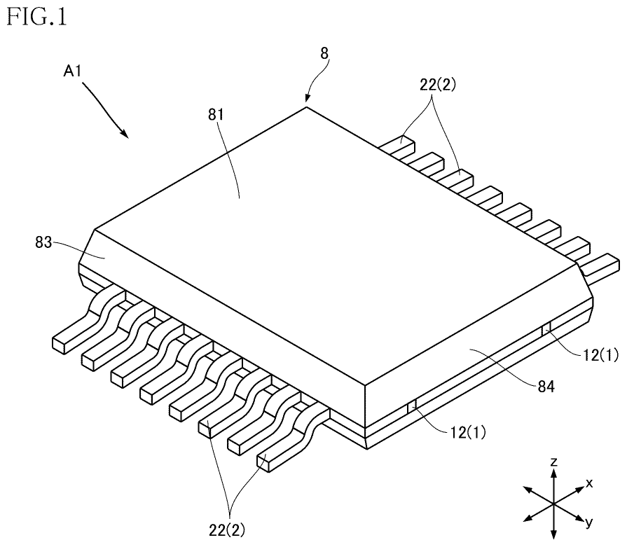

FIGS. 1 to 9 show a semiconductor device according to a first embodiment of the present disclosure. The semiconductor device A1 of this embodiment has a first lead 1, a plurality of second leads 2, a semiconductor element 6, a plurality of conductive members 71, and a sealing resin 8. The specific package structure or the like of the semiconductor device A1 is not limited in any way. The semiconductor device A1 may be an SOP (Small Outline Package).

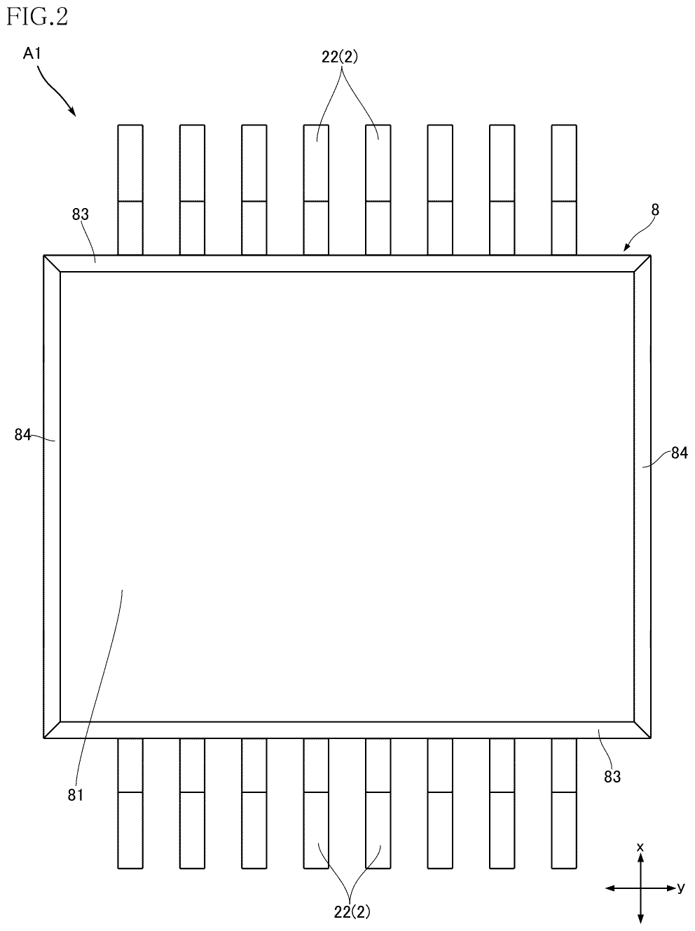

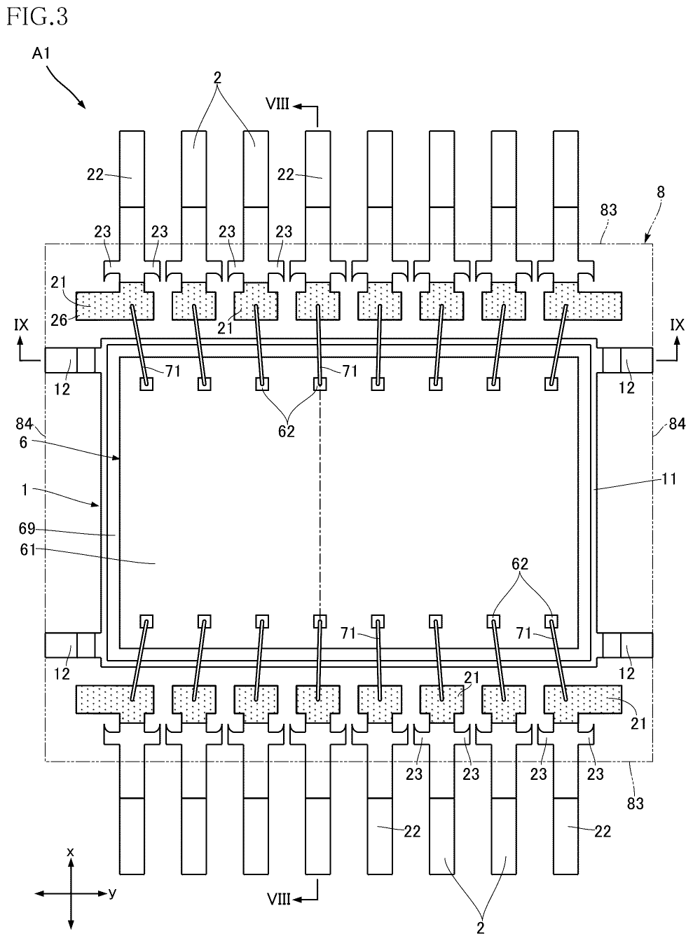

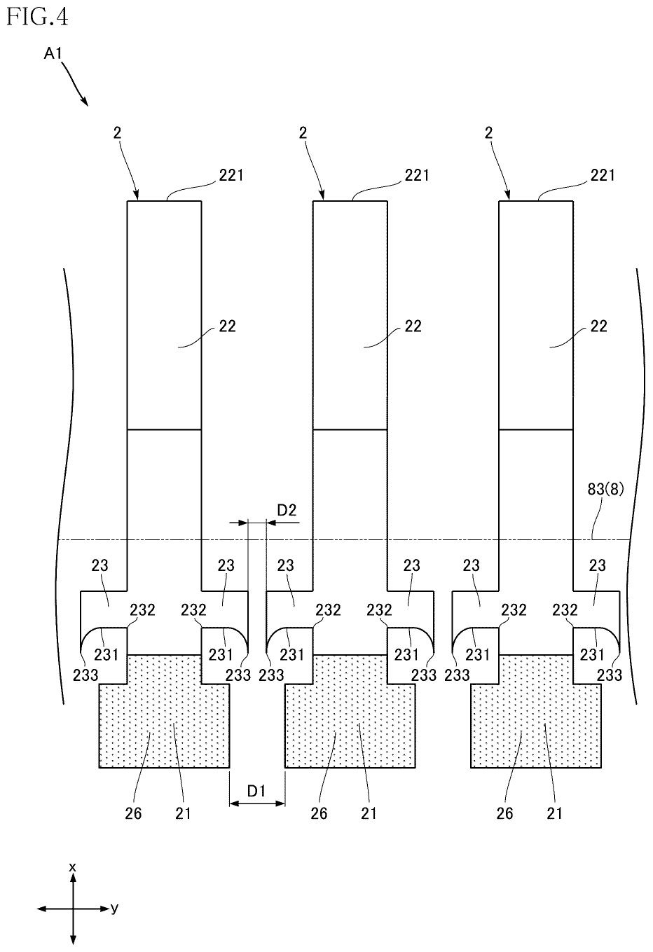

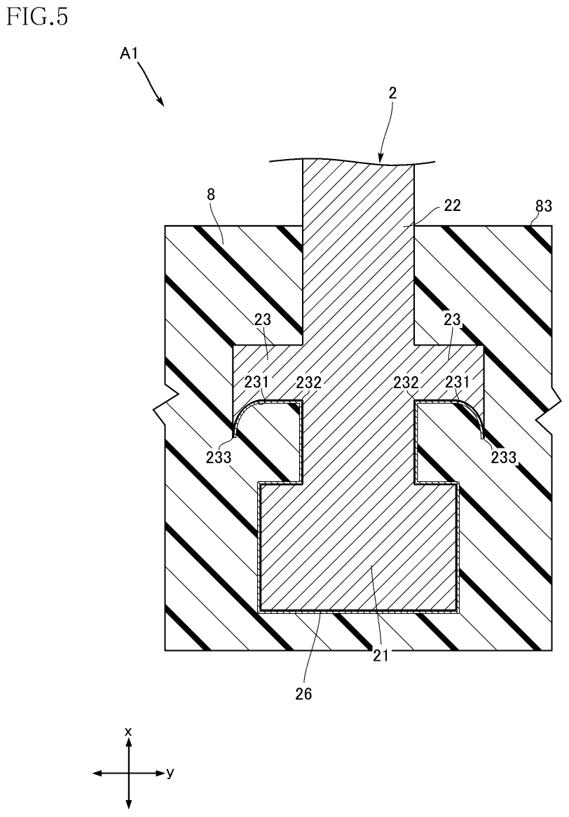

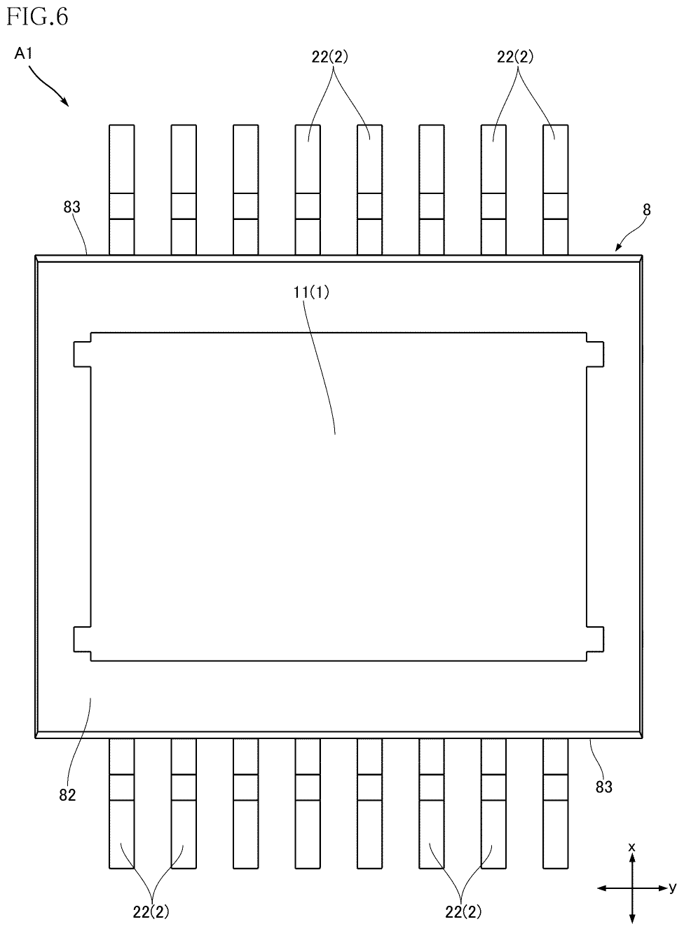

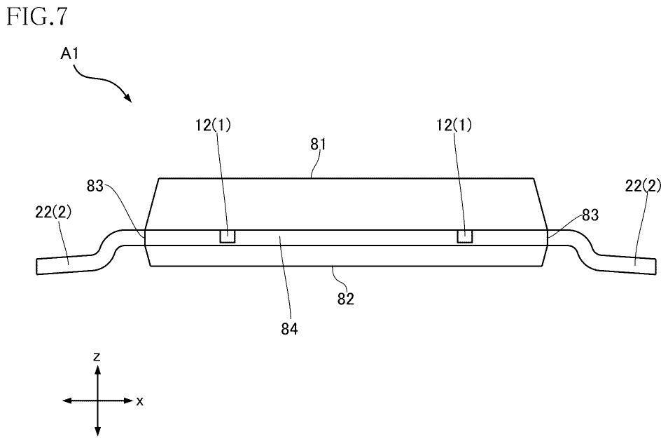

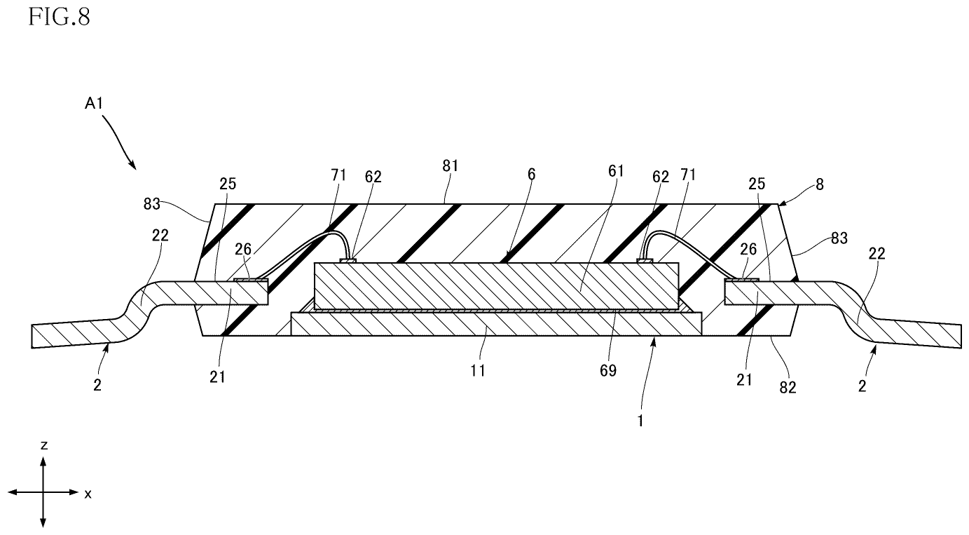

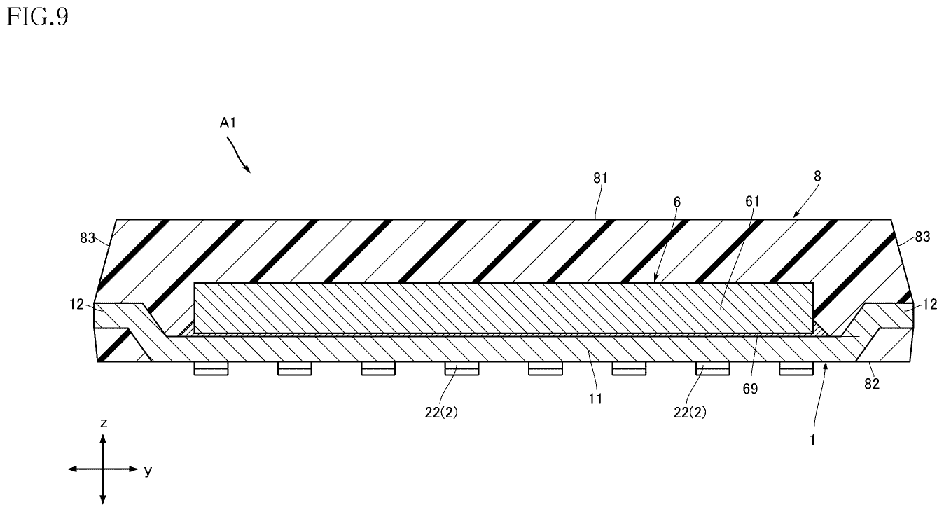

FIG. 1 is a perspective view showing the semiconductor device A1. FIG. 2 is a plan view showing the semiconductor device A1. FIG. 3 is a partial plan view showing the semiconductor device A1. FIG. 4 is an enlarged partial plan view showing the semiconductor device A1. FIG. 5 is an enlarged partial cross-sectional view showing the semiconductor device A1. FIG. 6 is a bottom view showing the semiconductor device A1. FIG. 7 is a side view showing the semiconductor device A1. FIG. 8 is a cross-sectional view along line VIII-VIII in FIG. 3. FIG. 9 is a cross-sectional view along line IX-IX in FIG. 3.

In these figures, for example, an example of a thickness direction in the present disclosure is a thickness direction z. Further, for example, an example of a direction intersecting the thickness direction z is a first direction x. Further, for example, an example of a direction intersecting the thickness direction z and the first direction x is a second direction y.

The sealing resin 8 covers the semiconductor element 6 and the plurality of conductive members 71. The sealing resin 8 may partially cover each of the first lead 1 and the plurality of second leads 2. The sealing resin 8 may include, for example, a black epoxy resin. The shape of the sealing resin 8 is not limited in any way and may have a resin main surface 81, a resin back surface 82, two resin side surfaces 83, and two resin side surfaces 84.

The resin main surface 81 may face one side of the thickness direction z. Resin main surface 81 may be flat, curved, bent, or the like. The resin back surface 82 may face the other side of the thickness direction z. The resin back surface 82 may be flat, curved, bent, or the like.

The two resin side surfaces 83 may be located between the resin main surface 81 and the resin back surface 82 in the thickness direction z. The two resin side surfaces 83 face opposite each other in the first direction x. The resin side surfaces 83 may be flat, curved, bent, or the like.

The two resin side surfaces 84 may be located between the resin main surface 81 and the resin back surface 82 in the thickness direction z. The two resin side surfaces 84 face opposite each other in the second direction y. The resin side surfaces 84 may be flat, curved, bent, or the like.

The first lead 1 has an island portion 11. The first lead 1 may further have a plurality of extending portions 12. The first lead 1 may be formed, for example, using a lead frame Lf to be described latEr. The first lead 1 may contain metal such as Cu (copper), Ni (nickel) and Fe (iron), or an alloy thereof.

The island portion 11 may be a flat plate-like portion positioned along an xy plane. The thickness direction z is the thickness direction of the island portion 11. The shape of the island portion 11 is not limited in any way and may be rectangular, for example. The island portion 11 may be exposed from the resin back surface 82.

The plurality of extending portions 12 extend from the island portion 11 in one sense of the y-direction. The plurality of extending portions 12 may serve a function of supporting the island portion 11 in a manufacturing method of the semiconductor device A1. The plurality of extending portions 12 may be exposed from the two resin side surfaces 84.

The plurality of second leads 2 are positioned apart from the first lead 1 as viewed in the thickness direction Z. The plurality of second leads 2 may be located on either side of the first direction x with respect to the first lead 1. Further, the plurality of second leads 2 may be aligned in the second direction y. The plurality of second leads 2 may be formed, for example, using a lead frame Lf to be described later. The second leads 2 may contain metal such as Cu (copper), Ni (nickel) and Fe (iron), or an alloy thereof.

The second lead 2 has a pad portion 21 and one or more protrusions 23. The second lead 2 may have an extending portion 22.

The pad portion 21 is the portion to which the conductive member 71 is connected. The specific shape and the like of the pad portion 21 are not limited in any way. The pad portion 21 may be rectangular.

The extending portion 22 may extend outwardly in the first direction x from the pad portion 21. The shape, size and the like of the extending portion 22 are not limited in any way. The size of the extending portion 22 in the second direction y is smaller than the size of the pad portion 21 in the second direction y. The extending portion 22 may protrude outwardly in the first direction x from the two resin side surfaces 83 of the sealing resin 8. A part of the extending portion 22 that protrudes from the resin side surfaces 83 may have a bent shape. The extending portion 22 has a tip portion 221. The tip portion 221 is a tip portion in the first direction x of the extending portion 22.

The second lead 2 may have a lead main surface 25. The lead main surface 25 may face one side in the thickness direction z.

The second lead 2 may have a metal layer 26. The metal layer 26 is located on a part of the lead main surface 25 that is included in the pad portion 21. The material of the metal layer 26 is not limited in any way and contains metal such as Ag (silver), Ni (nickel) and Pd (palladium), or an alloy thereof. In the illustrated example, the metal layer 26 is located on a part of the lead main surface 25 that is included in entirety of the pad portion 21 and a part of the extending portion 22.

The one or more protrusions 23 protrude in the second direction y. The one or more protrusions 23 may be located between the pad portion 21 and the tip portion 221 in the first direction x. The second lead 2 may have two protrusions 23. The two protrusions 23 may protrude opposed to each other in the second direction y. The protrusions 23 may be connected to the extending portions 22.

The protrusions 23 have a first surface 231. The first surface 231 is positioned along the thickness direction z. The first surface 231 faces the pad portion 21 side (inside) in the first direction x. The first surface 231 is covered with the sealing resin 8.

The first surface 231 has a first end 232 and a second end 233. The first end 232 is an end of the first surface 231 located on the root side in the second direction y. The second end 233 is an end of the first surface 231 located on the tip side in the second direction y. The second end 233 is located on a pad portion 21 side (inside) as viewed from the first end 232 in the first direction x.

The specific shape of the first surface 231 is not limited in any way. The first surface 231 may include a concave surface. The first surface 231 may include a plane located between said concave surface and the extending portion 22.

The width of the first surface 231 in the first direction x may be larger on a second end 233 side than on a first end 232 side.

The first surface 231 is covered by the sealing resin 8. The protrusions 23 are at least partially covered by the sealing resin 8. In the illustrated example, the entirety of the protrusion 23 may be covered by the sealing resin 8. A part of the extending portion 22 that is located opposite (outside) the pad portion 21 in the first direction x with respect to the protrusion 23 may be partially covered by the sealing resin 8.

A distance D2 in the second direction y between protrusions 23 facing each other of two adjacent second leads 2 is smaller than a distance D1 in the second direction y between pad portions 21 of two adjacent second leads 2.

FIG. 5 is an enlarged partial cross-sectional view of the second lead 2 in the vicinity of its central portion in the thickness direction z. As shown in the figure, the first surface 231 may be covered by a part of the metal layer 26. Side surfaces of the pad portion 21 and a part of the extending portion 22 between the pad portion 21 and the first surface 231 may be covered by the metal layer 26.

The semiconductor element 6 is an electronic component that performs a primary function of the semiconductor device A1. The specific shape of the semiconductor element 6 is not limited in any way and may be, for example, an LSI (Large Scale Integration). In the illustrated example, the semiconductor element 6 may have an element body 61 and a plurality of electrodes 62.

The element body 61 contains semiconductor material. The element body 61 may, for example, have a circuit portion (omitted in the illustration) for realizing an electrical function built into it. The shape of the element body 61 is not limited in any way and may, for example, have a cuboid shape. The element body 61 may be bonded to the island portion 11 by a bonding material 69. The bonding material 69 may be, for example, solder.

The plurality of electrodes 62 are used to electrically connect the semiconductor element 6 and the outside. The specific configuration of the plurality of electrodes 62 is not limited in any way. In the illustrated example, the plurality of electrodes 62 may be located on one side in the thickness direction z of the device body 61. The plurality of electrodes 62 may be arranged along four sides of the element body 61 as viewed in the thickness direction z.

The plurality of conducting members 71 electrically and individually connect the semiconductor element 6 and the plurality of second leads 2. In the illustrated example, the plurality of conductive members 71 may be connected to the pad portions 21 of the plurality of second leads 2 and the plurality of electrodes 62. The conductive members 72 may be wires, plate-like metal members, or the like. The conductive member 71 may contain metal such as Au (gold) and Cu (copper), or an alloy thereof. The conductive member 71 may be bonded to the metal layer 26 on the pad portion 21.

Next, operations of the semiconductor device A1 will be described.

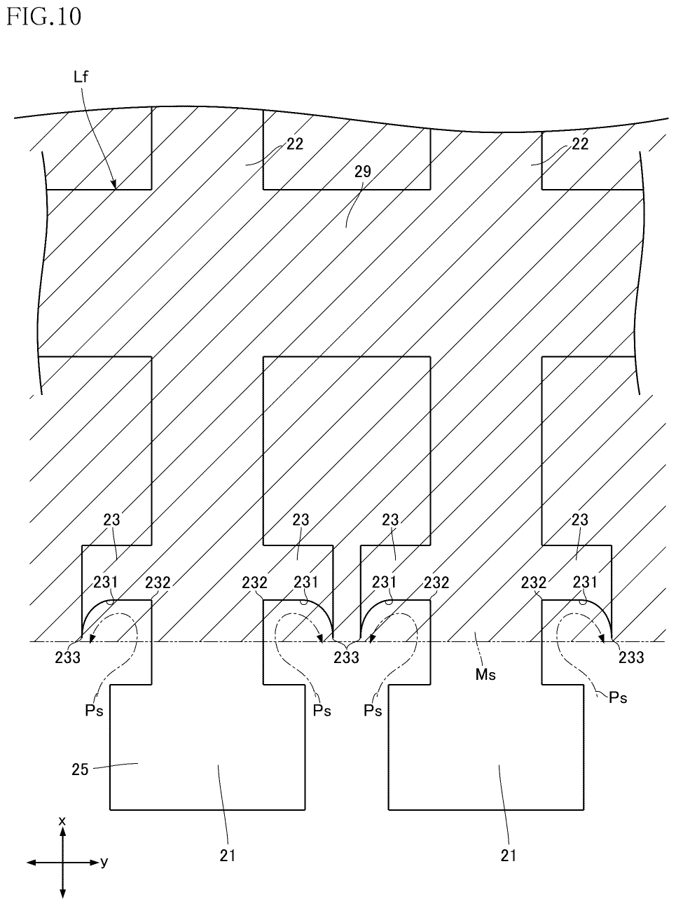

FIG. 10 is an enlarged partial plan view showing an example of the manufacturing method of the semiconductor device A1. The lead frame Lf includes a first lead 1 and a plurality of second leads 2, and may include a tie bar 29 that interconnects them. An area of the lead main surface 25 other than the area to be the pad portion 21 may be covered by a mask Ms. The mask Ms may be a plate-like material including, for example, resin or the like.

For example, plating may be used as a method to form the metal layer 26. In a case where plating is adopted, a plating solution Ps is applied to the lead frame Lf. In this case, the plating solution Ps can be spread into the space between adjacent second leads 2. The plating solution Ps can further flow toward the tip portion 221 or the like of the extending portion 22. The protrusion 23 has a first surface 231, and the second end 233 is located inside in the first direction x (on a pad portion 21 side) as viewed from the first end 232. This allows the plating solution Ps that tends to flow in to flow back toward the pad portion 21 side in the first direction x by flowing along the first surface 231. As a result, it is possible to reduce adhesion of the plating solution Ps to the part of the side surface positioned along the thickness direction z of the second lead 2 that is located outside in the first direction x (on the tip portion 221 side) from the first surface 231. Therefore, the metal layer 26 can be more appropriately arranged. Since the first surface 231 touches the plating solution Ps, the first surface 231 may be covered by the plating solution Ps in the semiconductor device A1.

Unlike the present embodiment, if the metal layer 26 is provided on the part of the extending portion 22 that protrudes from the sealing resin 8, there is concern that adjacent second leads 2 may improperly conduct due to phenomena such as migration or the like, for example, when a voltage difference occurs between multiple second leads 2. According to this embodiment, it is possible to suppress the provision of the metal layer 26 on the part of the extending portion 22 that protrudes from the sealing resin 8, thereby reducing such problems.

Adjacent second leads 2 have protrusions 23 opposed to each other. This can more reliably reduce the flow of the plating solution Ps to the tip portion 221 side.

As shown in FIG. 4, the distance D2 between the opposing protrusions 23 is smaller than the distance D1 between the adjacent pad portions 21. This can even more reliably reduce the flow of the plating solution Ps to the tip portion 221 side.

The first surface 231 includes a curved surface. This allows the flow of the plating solution Ps to be controlled more smoothly.

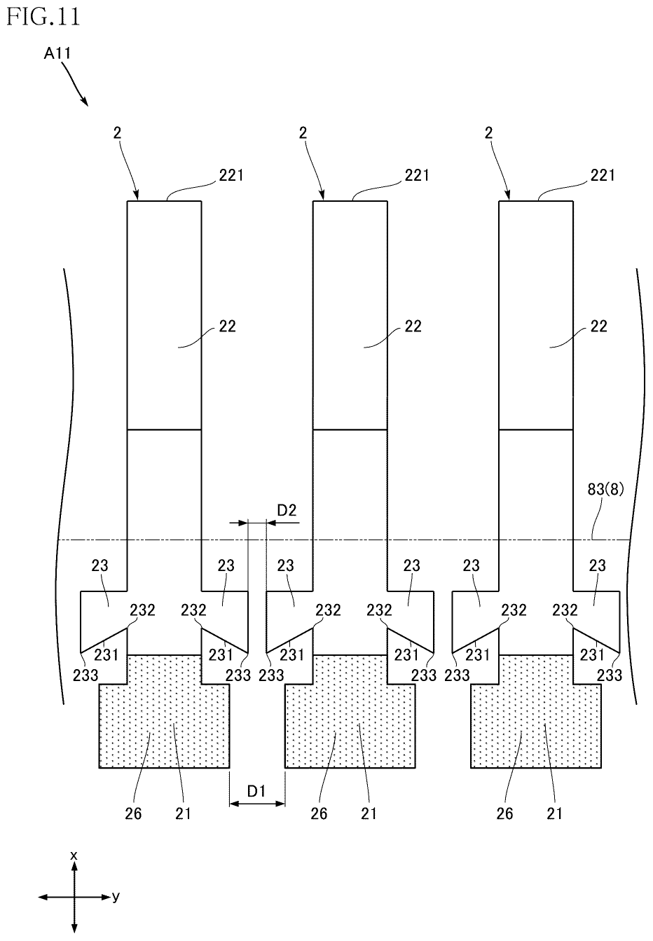

FIGS. 11 to 19 show variations and other embodiments of the present disclosure. In these figures, elements identical or similar to those of the above embodiment are marked with the same symbols as in the above embodiment. Further, the configurations of the respective parts in the respective variations and the respective embodiments can be combined with each other as appropriate to the extent that no technical contradiction arises.

FIG. 11 shows a first variation of the semiconductor device A1. In a semiconductor device A11 according to this variation, the first surface 231 is a flat surface. The first surface 231 is inclined with respect to the second direction y as viewed in the thickness direction z.

According to this variation, the metal layer 26 can be more appropriately arranged. As understood from this variation, the first surface 231 is not limited to a curved surface, but may be a flat surface.

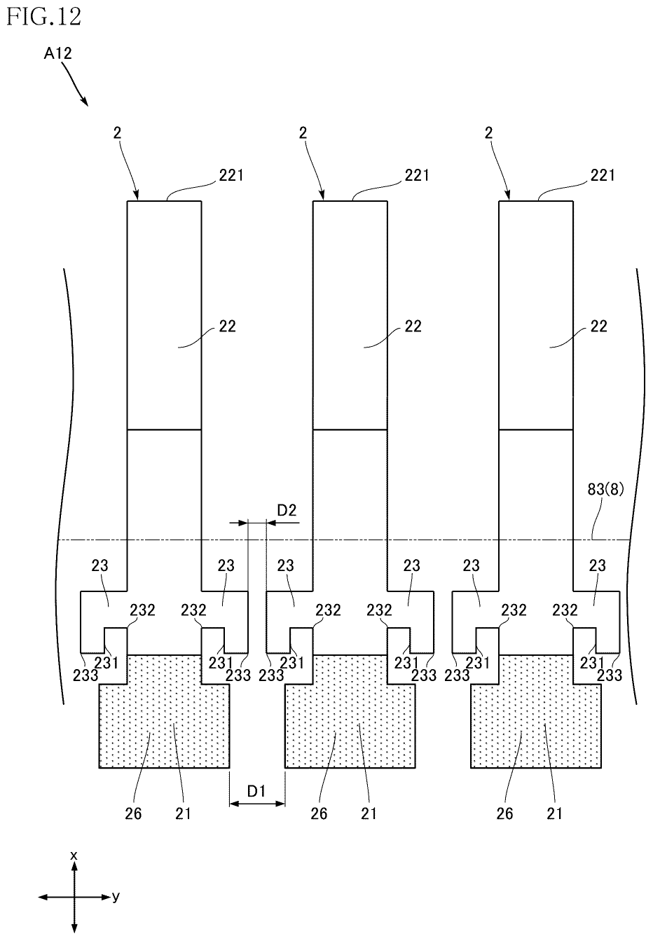

FIG. 12 shows a second variation of the semiconductor device A1. In a semiconductor device A12 according to this variation, the first surface 231 is a curved surface. The first surface 231 may have two step portions.

According to this variation, the metal layer 26 can be more appropriately arranged. As understood from this variation, the first surface 231 may be to have stepped portions.

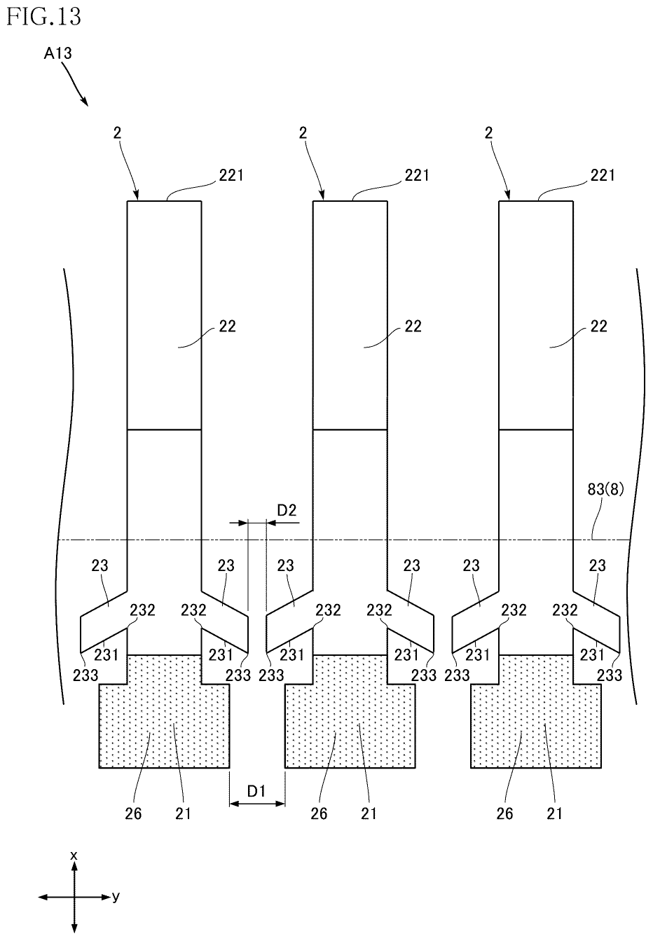

FIG. 13 shows a third variation of the semiconductor device A1. In a semiconductor device A13 according to this variation, the first surface 231 is a flat surface. The first surface 231 is inclined with respect to the second direction y as viewed in the thickness direction z. The width of the protrusion 23 in the first direction x is constant. The protrusion 23 as a whole is inclined with respect to the second direction y.

According to this variation, the metal layer 26 can be more appropriately arranged. As understood from this variation, the width of the protrusion 23 in the first direction x is not limited to a configuration in which the width increases as it gets closer to the tip side, but may be constant.

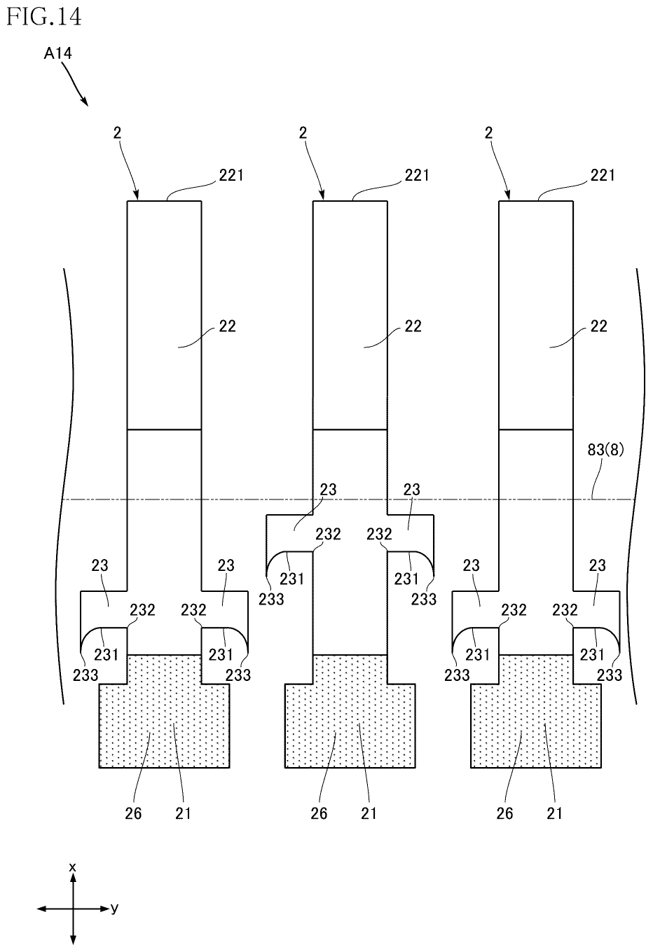

FIG. 14 shows a fourth variation of the semiconductor device A1. In a semiconductor device A14 according to this variation, the protrusions 23 opposed to each other of the two adjacent second leads 2 may have different positions in the first direction x. Also, the two protrusions 23 of one second lead 2 have equal positions in the first direction x.

According to this variation, the metal layer 26 can be arranged more appropriately. According to this variation, it is possible to extend the distance between the protrusions 23 opposed to each other of the adjacent second leads 2, thereby reducing problems such as short-circuiting.

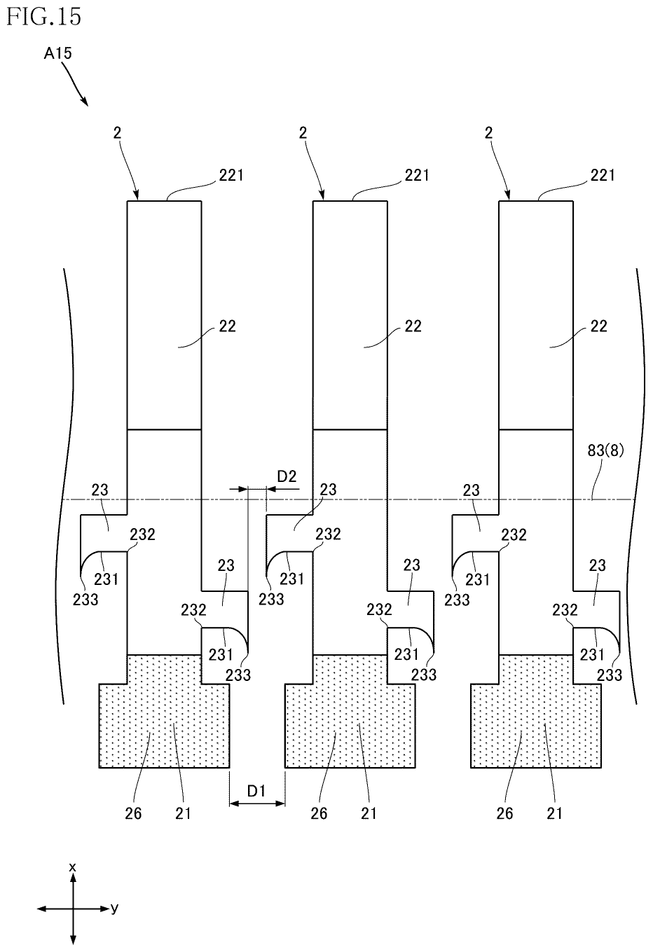

FIG. 15 shows a fifth variation of the semiconductor device A1. In a semiconductor device A15 according to this variation, the protrusions 23 opposed to each other of the two adjacent second leads 2 may have different positions in the first direction x. Also, the two protrusions 23 of one second lead 2 have mutually different positions in the first direction x.

According to this variation, the metal layer 26 can be positioned more appropriately. According to this variation, it is possible to extend the distance between the protrusions 23 opposed to each other of the adjacent second leads 2, thereby reducing problems such as short-circuiting.

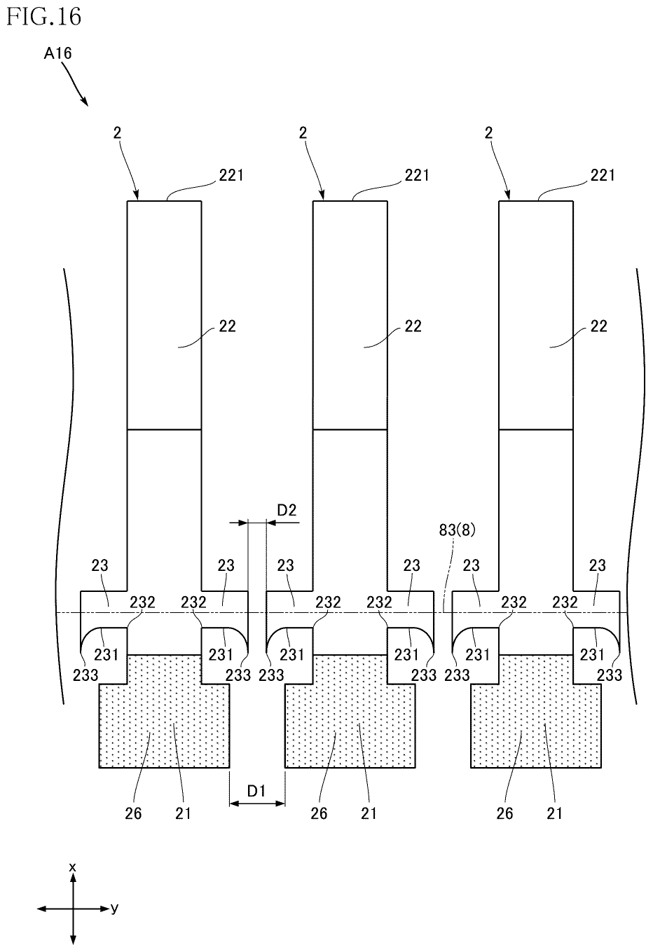

FIG. 16 shows a sixth variation of the semiconductor device A1. In a semiconductor device A16 according to this variation, the protrusions 23 may be partially exposed from the sealing resin 8. In the illustrated example, the resin side surface e 83 intersects the protrusion 23 in the vicinity of the central part of the protrusion 23 in the first direction x as viewed in the thickness direction z.

According to this variation, the metal layer 26 can be more appropriately arranged. As understood from this variation, if the configuration is such that the first surface 231 is covered by the sealing resin 8, the rest of the protrusions 23 may be exposed from the sealing resin 8.

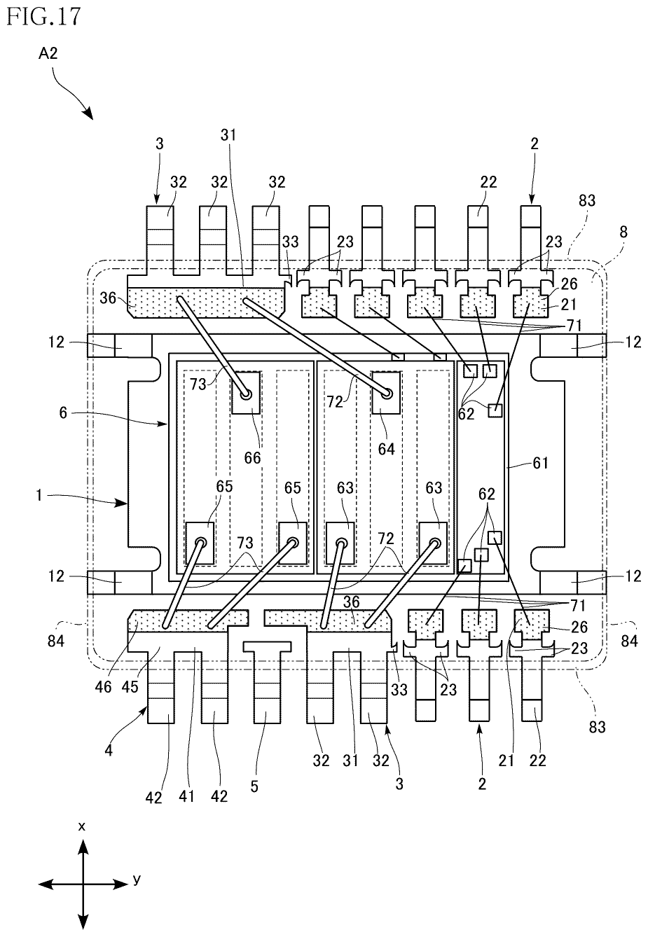

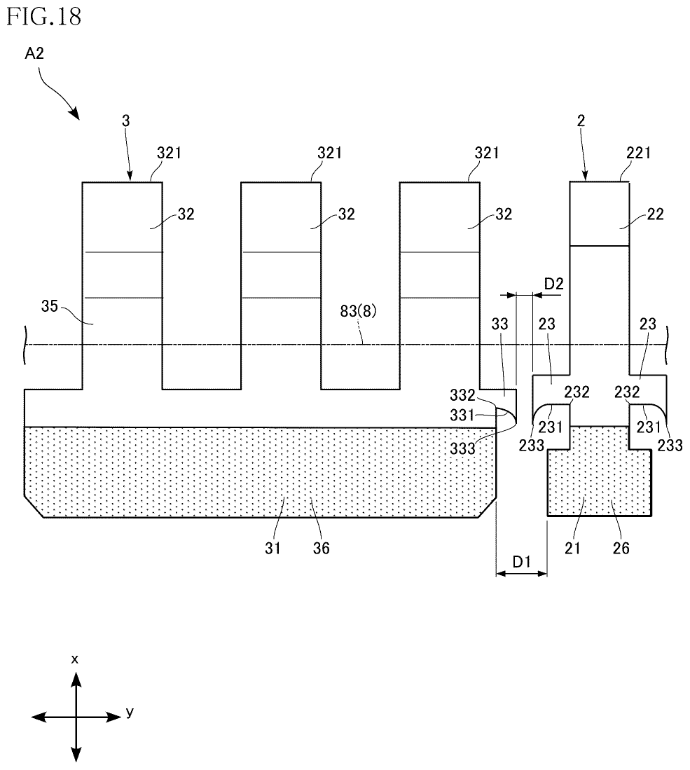

FIGS. 17 and 18 show a semiconductor device according to a second embodiment of the present disclosure. A semiconductor device A2 according to this embodiment has a plurality of second leads 2 and a plurality of second leads 3. The semiconductor device A2 may be provided with a third lead 4 and a fourth lead 5.

The plurality of second leads 3 are located apart from the first lead 1 and the plurality of second leads 2 as viewed in the thickness direction z. The plurality of second leads 3 may be located on either side of the first direction x with respect to the first lead 1. The plurality of second leads 3 may be formed, for example, using a lead frame Lf. The second leads 3 may contain metal such as Cu (copper), Ni (nickel) and Fe (iron), or an alloy thereof.

The second lead 3 has a pad portion 31 and one or more protrusions 33. The second lead 3 may have a plurality of extending portions 32.

The pad portion 31 is a portion to which a conductive member 72 and a conductive member 73 are connected. The specific shape and the like of the pad portion 31 are not limited in any way. The pad portion 31 may be rectangular.

The plurality of extending portions 32 may extend outwardly in the first direction x from the pad portion 31. The plurality of extending portions 32 may be aligned in the second direction y. The shape, size and the like of the extending portions 32 are not limited in any way. The size of the extending portions 32 in the second direction y is smaller than the size of the pad portion 31 in the second direction y. The extending portion 32 may protrude outwardly in the first direction x from the two resin side surfaces 83 of the sealing resin 8. The part of the extending portion 32 that protrudes from the resin side surfaces 83 may have a bent shape. The extending portion 32 has a tip portion 321. The tip portion 321 is a tip portion in the first direction x of the extending portion 32.

The second lead 3 may have a lead main surface 35. The lead main surface 35 may face one side in the thickness direction z.

The second lead 3 may have a metal layer 36. The metal layer 36 is located on a part of the lead main surface 35 that is included in the pad portion 31. The material of the metal layer 36 is not limited in any way and contains metal such as Ag (silver), Ni (nickel) and Pd (palladium), or an alloy thereof. In the illustrated example, the metal layer 36 is located on the part of the lead main surface 35 that is included in the entirety of the pad portion 31 and a part of the extending portion 32.

The one or more protrusions 33 protrude in the second direction y. The one or more protrusions 33 may be continuous in the second direction y from the pad portions 31. The second lead 3 may have one protrusion 33. The one protrusion 33 may be opposed to the protrusion 23 of the adjacent second lead 2.

The protrusion 33 has a first surface 331. The first surface 331 is positioned along the thickness direction z. The first surface 331 faces the pad portion 31 side (inside) in the first direction x. The first surface 331 is covered by the sealing resin 8.

The first surface 331 has a first end 332 and a second end 333. The first end 332 is an end of the first surface 331 located on the root side in the second direction y. The second end 333 is an end located on the tip side in the second direction y of the first surface 331. The second end 333 is located on the pad portion 31 side (inside) in the first direction x as viewed from the first end 332.

The specific shape of the first surface 331 is not limited in any way. The first surface 331 may include a concave surface. The first surface 331 may include a plane located between said concave surface and the extending portion 32.

The width of the first surface 331 in the first direction x may be larger on a second end 333 side than on a first end 332 side.

The first surface 331 is covered by the sealing resin 8. The protrusions 33 are at least partially covered by the sealing resin 8. In the illustrated example, the entirety of the protrusion 33 may be covered by the sealing resin 8. A part of the extending portion 32 that is located opposite (outside) the pad portion 31 in the first direction x as viewed from the protrusion 33 may be covered by the sealing resin 8.

The protrusion 33 may be located at the same (or at approximately the same) position in the first direction x as the protrusion 23 of the adjacent second lead 2.

The third lead 4 is located opposite the plurality of second leads 2 in the second direction y with respect to one second lead 3. The third lead 4 may be formed, for example, using a lead frame Lf. The third lead 4 may contain metal such as Cu (copper), Ni (nickel) and Fe (iron), or an alloy thereof.

The third lead 4 may have a pad portion 41 and a plurality of extending portions 42.

The pad portion 41 is the portion to which the conductive member 73 is connected. The specific shape and the like of the pad portion 41 are not limited in any way. The pad portion 41 may be rectangular.

The plurality of extending portions 42 may extend outwardly in the first direction x from the pad portion 41. The plurality of extending portions 42 may be aligned in the second direction y. The shape, size and the like of the extending portions 42 are not limited in any way. The size of the extending portions 42 in the second direction y is smaller than the size of the pad portion 41 in the second direction y. The extending portion 42 may protrude outwardly in the first direction x from the two resin side surfaces 83 of the sealing resin 8. The part of the extending portion 42 protruding from the resin side surfaces 83 may have a bent shape.

The third lead 4 may have a lead main surface 45. The lead main surface 45 may face one side in the thickness direction z.

The third lead 4 may have a metal layer 46. The metal layer 46 is located on the part of the lead main surface 45 that is included in the pad portion 41. The material of the metal layer 46 is not limited in any way and contains metal such as Ag (silver), Ni (nickel) and Pd (palladium), or an alloy thereof. In the illustrated example, the metal layer 46 is located on the part of the lead main surface 45 that is included in entirety of the pad portion 41 and a part of the extending portion 42.

The fourth lead 5 may be located between the second lead 3 and the third lead 4. In the illustrated example, the fourth lead 5 does not have to be in conduction with the semiconductor element 6. The fourth lead 5 protrudes outwardly in the first direction x from the resin side surface 83. The fourth lead 5 may be a so-called dummy lead.

The semiconductor element 6 according to the present disclosure may include two switching elements and a drive IC. The two switching elements may be MOSFETs (Metal Oxide Semiconductor Field Effect Transistors). These switching elements are not limited to MOSFETs, and for example, they may be other transistors such as bipolar transistors and IGBTs (Insulated Gate Bipolar Transistors).

An electrode 63 of one of the switching elements is connected to the pad portion 31 of one of the second leads 3 by a conductive member 72. The electrode 63 may be, for example, a drain electrode. An electrode 64 of the switching element is connected to the pad portion 31 of the other one of the second leads 3 by the conductive member 72. The electrode 64 may be, for example, a source electrode.

An electrode 65 of the other one of the switching elements is connected to the pad portion 41 of the third lead 4 by the conductive member 73. The electrode 65 may be, for example, a source electrode. An electrode 66 of said switching element is connected to the pad portion 31 of the other one of the second leads 3 by the conductive member 73. The electrode 66 may be, for example, a drain electrode.

The drive IC is an element that performs switching control of the two switching elements. This drive IC is connected to the gate electrodes (not shown in the figures) of the two switching elements. The plurality of electrodes 62 of this drive IC are connected to the pad portions 21 of the plurality of second leads 2 by the plurality of conductive members 71.

According to this embodiment, the metal layer 36 can be more appropriately arranged. As can be understood from this embodiment, if a plurality of extending portions 32 are connected to a pad portion 31, the presence of a part of the pad portions 31 located between adjacent extending portions 32 can prevent the second lead 3 from slipping out of the sealing resin 8 in the first direction x. In such a configuration, the metal layer 36 can be more appropriately arranged by having protrusions 33.

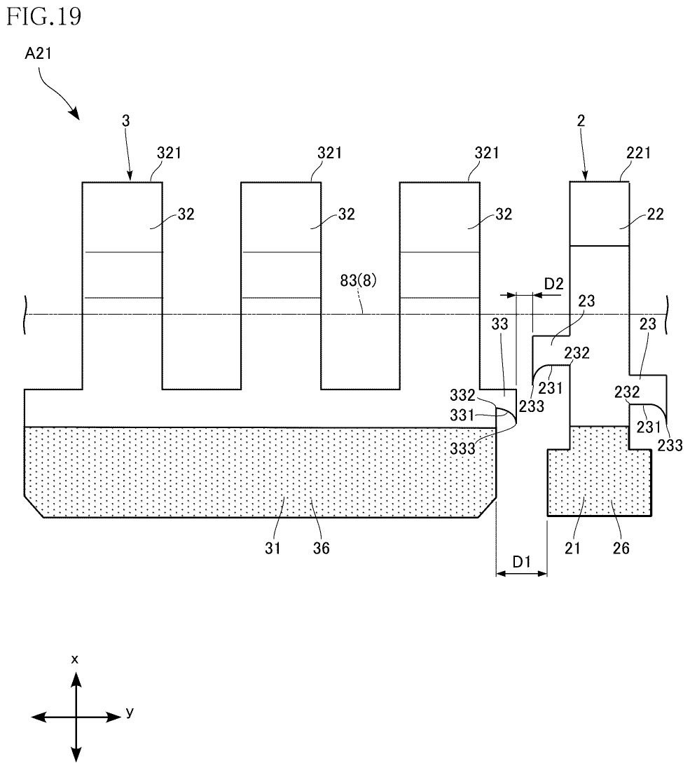

FIG. 19 shows a first variation of the semiconductor device A2. In this variation, the protrusion 33 and the protrusions 23 of the adjacent second lead 2 have different positions in the first direction x with respect to each other.

According to this variation, the metal layer 26 and the metal layer 36 can be more appropriately arranged. The distance between the protrusion 23 and the protrusion 33 can be extended, and unintended short-circuiting and the like can be reduced.

The semiconductor devices according to the present disclosure are not limited to the embodiments described above. The specific configuration of each part of the semiconductor devices according to the present disclosure can be designed and modified in various ways. The present disclosure includes the configurations relating to the following clauses.

### Clause 1.

A semiconductor device (A1) comprising:
a semiconductor element (6);
a first lead (1) having an island portion (11) for carrying the semiconductor element (6);
a second lead (2) having a pad portion (21);
a conductive member (71) connected the to semiconductor element (6) and the pad portion (71); and
a sealing resin (8) covering the semiconductor element (6), the pad portion (21) and the conductive member (71),
wherein the second lead (2) protrudes from the sealing resin (8) in a first direction (x) intersecting a thickness direction (z) of the island portion (11),
the second lead (2) has a metal layer (26) provided on the pad portion (21) and a protrusion (23) to protrude in a second direction (y) intersecting the first direction (x) and the thickness direction (z),
the protrusion (23) has a first surface (231) being positioned along the thickness direction (z), facing a pad portion (21) side in the first direction (x), and being covered by the sealing resin (8),
the first surface (231) has a first end (232) on a root side and a second end (233) on a tip side, and
the second end (233) is located on a pad portion (21) side as viewed from the first end (232) in the first direction (x).

### Clause 2.

The semiconductor device (A1) according to clause 1, wherein the first surface (231) includes a curved surface.

### Clause 3.

The semiconductor device (A11) according to clause 1, wherein the first surface (231) is a flat surface.

### Clause 4.

The semiconductor device (A1) according to any one of clauses 1 to 3, wherein a width of the protrusion (23) in the first direction (x) increases as it gets closer to a tip.

### Clause 5.

The semiconductor device (A13) according to any one of clauses 1 to 3, wherein a width of the protrusion (23) in the first direction (x) is constant.

### Clause 6.

The semiconductor device (A1) according to any one of clauses 1 to 5, wherein the first surface (231) is covered by the metal layer (26).

### Clause 7.

The semiconductor device (A1) according to any one of clauses 1 to 6, wherein the second lead (2) has two protrusions (23) protruding on both sides in the second direction (y).

### Clause 8.

The semiconductor device (A14) as described in clause 7, wherein said projections (23) of said two adjacent second leads (2) facing each other are in different positions in said first direction (x).

### Clause 9.

The semiconductor device (A14) according to clause 8, wherein the two protrusions (23) opposed to each other of the two adjacent second leads (2) are at a same position in the first direction (x).

### Clause 10.

The semiconductor device (A15) according to clause 8, wherein the two protrusions (23) opposed to each other of the two adjacent second leads (2) are at different positions in the first direction (x).

### Clause 11.

The semiconductor device (A1) according to any one of clauses 7 to 9, wherein a distance (D2) between the two protrusions (23) opposed to each other of the two adjacent second leads (2) is smaller than another distance (D1) between pad portions (21) of the two adjacent second leads (2).

### Clause 12.

The semiconductor device (A1) according to any one of clauses 1 to 10, wherein an entirety of the protrusion (23) is covered by the sealing resin (8).

### Clause 13.

The semiconductor device (A16) according to any one of clauses 1 to 10, wherein the protrusion (23) is partially exposed from the sealing resin (8).

### Clause 14.

The semiconductor device (A2) according to any one of clauses 1 to 12, wherein the second lead (2) has a plurality of extending portions (22) connected to the pad portion (21).

### Clause 15.

The semiconductor device (A2) according to clause 14, wherein the protrusion (23) is connected to the pad portion (21).

REFERENCE NUMERALS

| | |
|---|---|
| A1, A11, A12, A13, A14, A15, | |
| A16, A2: Semiconductor device | |
| 1: First lead | 2, 3: Second lead |
| 4: Third lead | 5: Fourth lead |
| 6: Semiconductor device | 8: Sealing resin |
| 11: Island portion | 12: Extending portion |
| 21: Pad portion | 22: Extending portion |
| 23: Protrusion | 25: Lead main surface |
| 26: Metal layer | 31: Pad portion |
| 32: Extending portion | 33: Protrusions |
| 35: Lead main surface | 36: Metal layer |
| 41: Pad portion | 42: Extending portion |
| 45: Lead surface | 46: Metal layer |
| 61: Element body | 62, 63, 64, 65: Electrode |
| 66: Semiconductor device | 69: Bonding material |
| 71, 72, 73: Conductive member | 81: Resin main surface |
| 82: Resin back surface | 83, 84: Resin side surface |
| 221: Tip portion | 231: First surface |
| 232: First end | 233: Second end |
| 321: Tip portion | 331: First surface |
| 332: First end | 333: Second end |
| D1, D2: Distance | IC: Drive |
| Lf: Lead frame | x: Direction 1 |
| y: Second direction | z: Thickness direction |

1. A semiconductor device comprising:
a semiconductor element;
a first lead having an island portion for carrying the semiconductor element;
a second lead having a pad portion;
a conductive member connected to the semiconductor element and the pad portion; and
a sealing resin covering the semiconductor element, the pad portion and the conductive member,
wherein the second lead protrudes from the sealing resin in a first direction intersecting a thickness direction of the island portion,
the second lead has a metal layer provided on the pad portion and a protrusion to protrude in a second direction intersecting the first direction and the thickness direction,
the protrusion has a first surface being positioned along the thickness direction, facing a pad portion side in the first direction, and being covered by the sealing resin,
the first surface has a first end on a root side and a second end on a tip side, and
the second end is located on a pad portion side as viewed from the first end in the first direction.

2. The semiconductor device according to claim 1, wherein the first surface includes a curved surface.

3. The semiconductor device according to claim 1, wherein the first surface is a flat surface.

4. The semiconductor device according to claim 1, wherein a width of the protrusion in the first direction increases as it gets closer to a tip.

5. The semiconductor device according to claim 1, wherein a width of the protrusion in the first direction is constant.

6. The semiconductor device according to claim 1, wherein the first surface is covered by the metal layer.

7. The semiconductor device according to claim 1, wherein the second lead has two protrusions protruding on both sides in the second direction.

8. The semiconductor device as described in claim 7, wherein said projections of said two adjacent second leads facing each other are in different positions in said first direction.

9. The semiconductor device according to claim 8, wherein the two protrusions opposed to each other of the two adjacent second leads are at a same position in the first direction.

10. The semiconductor device according to claim 8, wherein the two protrusions opposed to each other of the two adjacent second leads are at different positions in the first direction.

11. The semiconductor device according to claim 7, wherein a distance between the two protrusions opposed to each other of the two adjacent second leads is smaller than another distance between pad portions of the two adjacent second leads.

12. The semiconductor device according to claim 1, wherein an entirety of the protrusion is covered by the sealing resin.

13. The semiconductor device according to claim 1, wherein the protrusion is partially exposed from the sealing resin.

14. The semiconductor device according to claim 1, wherein the second lead has a plurality of extending portions connected to the pad portion.

15. The semiconductor device according to claim 14, wherein the protrusion is connected to the pad portion.
